(19) United States
(12) Patent Application Publication
(10) Pub. No.: US 2008/0224690 A1
(43) Pub. Date: Sep. 18, 2008

(54) Embedded Directional Power Sensing

(75) Inventors: Dean B. NICHOLSON, Windsor, CA (US); Jonathan B. SCOTT, Hamilton (NZ)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 12/131,050

(22) Filed: May 31, 2008

(51) Int. Cl. G01R 1/04; G01R 19/00

(52) U.S. Cl. 324/156; 324/76.11

(57) ABSTRACT

A module incorporates power sensors coupled to a through line through directional couplers, all of which are mounted on a board within a housing, for measuring transmitted and received power of a system under test.

### BACKGROUND OF THE INVENTION

FIG. 1 shows an example of a prior-art apparatus 100 for measuring transmitted and received power from a “system under test” 101. Here the term “system under test” can include a “device under test”. The apparatus can be used to measure the power transmitted from and received by a cellular base station or microwave test instrumentation, for example. Typically, directional couplers 103, 105 are attached at opposite ends of a through section 107. The directional couplers 103, 105 and through section 107 can be made from waveguide or transmission line.

Attached to a coupled port 113 of the directional coupler 105 is a power sensor 117. Attached to a coupled port 115 of the directional coupler 103 is a power sensor 119.

The power sensors 117, 119 can be, for example, heat-based power sensors (also referred to as thermal-based power sensors) or rectification sensors (such as diode-based sensors). The power sensors 117, 119 can be Agilent 8481A Power Sensors, for example, controlled by Agilent E4418B Power Meters (not shown). Agilent is a trademark of Agilent Technologies, Inc. of Santa Clara, Calif., USA.

The power sensor 117 receives a portion of the power of a system output RF signal 121 through the coupled port 113 of the directional coupler 105.

The power sensor 119 receives a portion of the power of a RF signal 123 received through the coupled port 115 of the directional coupler 103.

One problem with this prior-art setup is that the separate components need to be specified and calibrated separately. The power sensors 117, 119 and the directional couplers 103, 105 all must first be separately calibrated before being integrated into the functioning apparatus 100. In order to accurately account for the reflections and Gain vs. Frequency of this apparatus 100, the user must then recalibrate the combined assembly.

Another problem is the relatively large size, high power loss and high cost of the apparatus 100.

It would be desirable to provide a pre-calibrated, compact, low loss and inexpensive module for measuring the transmitted and received power of a system under test such as a cellular base station or microwave test instrumentation.

### SUMMARY OF THE INVENTION

A module incorporates power sensors coupled to a through line through directional couplers, all of which are mounted on a board within a housing, for measuring transmitted and received power of a system under test.

### BRIEF DESCRIPTION OF THE DRAWINGS

Further preferred features of the invention will now be described for the sake of example only with reference to the following figures, in which:

FIG. 1 shows an example of a prior-art apparatus for measuring transmitted and received power from a “system under test”.

FIG. 2 is a diagrammatic view of an embodiment of the power-sensor module of the present invention.

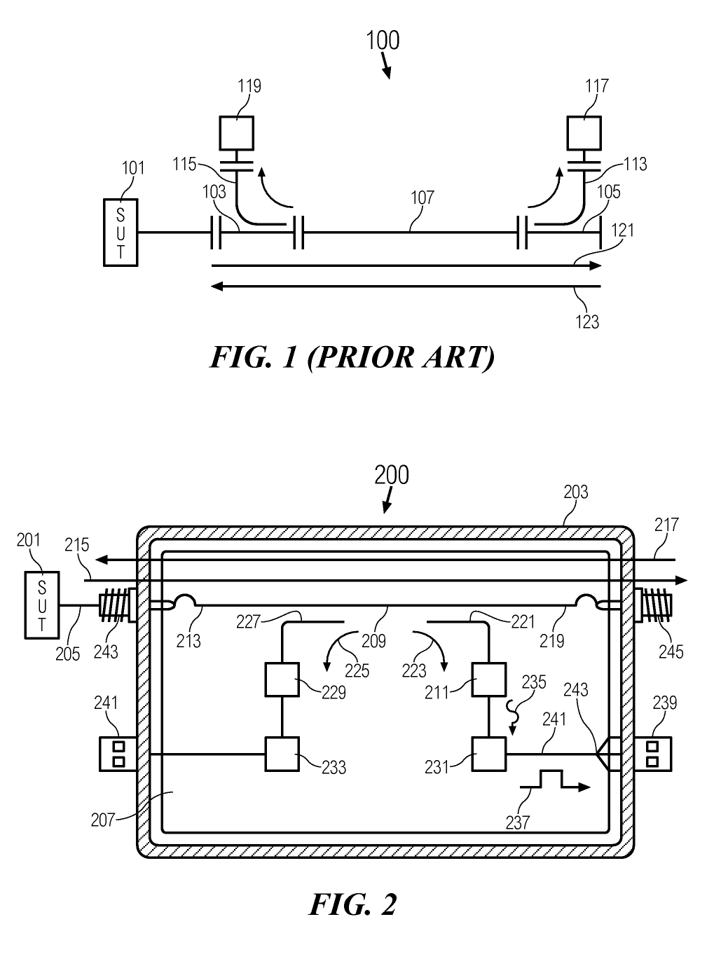

### DETAILED DESCRIPTION

A module incorporates power sensors coupled to a through path through directional couplers, all of which are on a board within a housing. The module measures transmitted and received power of a system under test.

FIG. 2 is a diagrammatic view of an embodiment of the present invention. A power-sensor module 200 is connected to a “system under test” 201. The module 200 can be connected to the system under test 201 through a transmission path 205 which can be a cable, for example. Alternatively the transmission path 205 can be a path through the air (“wirelessly”) in the case where antennae are used to transmit power between the module 200 and system under test 201. The module 200 is used for measuring power transmitted from the system under test 201 and power received by the system under test 201. The term “system under test” can include a “device under test” and can refer to a cellular base station or to microwave test instrumentation, for example. The module 200 can be used for such applications as measuring the power transmitted from and received by the cellular base station or microwave test instrumentation.

The module 200 includes a board 207, a through path 209 mounted to the board 207, a first power sensor 211 mounted to the board 207, an input 213 of the through path 209 for receiving a first signal 215, an output 219 of the through path 209 for outputting the first signal 215, and a first coupler 221 for transmitting a portion of the first signal 223 to the first power sensor 211 for determining the power of the first signal 215.

In one embodiment the first signal 223 has a frequency in the RF range. The RF frequency range is considered to cover frequencies from approximately 150 kHz up to the IR range. In other embodiments the frequency can be in the microwave frequency range of 1 GHz and higher or the frequency can be in the optical range. The transmission media 207 can be cable, waveguide, air or other media.

The input 213 of the through path 209 can be electrically connected to the transmission path 205 via a connector 243, which can be a coaxial cable plug, for example.

The first power sensor 211 outputs an output power measurement signal 235 which can be an analog signal. The signal 235 indicates the power measured by the first power sensor 211. The signal can be output to an external device, such as a multimeter or oscilloscope, through a power measurement output path 241 and a power measurement output 243.

The module 200 also includes a second power sensor 229 mounted to the board 207. The output 219 of the through path 209 can additionally receive a second signal 217, in which case the input 213 of the through path 209 will output the second signal 217 when it passes through the through path 209. The second signal 217 is the power received by the system under test 201. A second coupler 227 transmits a portion of the second signal 225 to the second power sensor 229 for determining the power of the second signal 217. Alternatively, the second coupler 227 can transmit a portion of the second signal 217 to a devise outside of or external from the module 200 for determining the power of the second signal 217. An output power measurement signal can be output from the second power sensor 229 similarly to as described with respect to the first power sensor 211.

The output 219 of the through path 209 can be electrically connected to a cable to receive the second signal 217 via a connector 245, which can be a coaxial cable plug.

The board 207 can in general be a flat piece of material designed for a special purpose, for example a supporting structure which can support the components of the module 200. The board can be a substrate (the supporting material on or in which the parts of an integrated circuit are attached or made), a printed circuit board (a flat plate or base of insulating material containing a pattern of conducting material, for example a ceramic, Teflon, PTFE, fused silica, glass or fiberglass substrate), or an integrated circuit substrate (also known as also known as an IC, microcircuit, microchip, silicon chip, or chip).

The through path 209 can be any type of line or combination of lines which can transmit power between the input 213 and output 219. For example, it can be a wire, a fiber optic cable, a thin film on a substrate, a conductive transmission line etched on a substrate, or a conductive material such as a conductive semiconductor material or metallic conductor. It can be the conducting material of co-planer waveguide, microstrip or stripline.

Likewise, the couplers 221, 227 can be any type of line or combination of lines which can transmit the portion of the first signal 223 and the portion of the second signal 225 to the first power sensor 211 and second power sensor 229. The couplers 221, 227 can be directional couplers formed from conductive material etched or otherwise placed on the board 207. For example, the couplers 221, 227 can be microstrip directional couplers.

The first power sensor 211 and second power sensor 225 can be, for example, heat-based power sensors (also referred to as thermal-based power sensors) or rectification sensors (such as diode-based sensors), and can be mounted on the board 207 using surface mount technology (SMT).

When the output power measurement signal 235 output from the first power sensor 211 is an analog signal, the module 200 can include an analog-to-digital converter 231 to digitize the signal 235 and output a digital power measurement signal 237. Both the analog signal 235 and the digital signal 237 contain information representing the power of the portion of the first signal 223. The analog-to-digital converter 231 can be mounted to the board 207 using surface mount technology (SMT). The digital power measurement signal 237 can be output through the power measurement output path 241 to the power measurement output 243. In the case of the digital signal 237, the output path 241 is a digital bus. The signal 235 and path 241 can be arranged for use with the USB standard. The digital signal 237 can then be output through an output port 239, which can include a USB or other digital connector, to an external device, such as a multimeter or oscilloscope, for indicating the power of the first signal 215.

The digital signal 237 can be formatted and output from the module 200 using protocols such as USB, Ethernet, LAN, RS232, IEEE 1394, GPIB, HPIB, VXI, PCI Express, PCI, PXI, LXI, PCMCIA or others as known in the art.

Alternatively, the output port 215 can be a transmitter and the signal 217 can be transmitted through the air to a receiver at the measurement device 213. In this case the wireless format can be WiFi, WUSB or IrDA.

Alternatively, rather than the analog-to-digital converter 231, a power meter can be mounted on the board 207 for converting the signal 235.

The module 200 can include another analog-to-digital converter 233 for digitizing a signal output by the second power sensor 229 indicating the power of the second signal 217. This is similar to that described with respect to the analog-to-digital converter 231 and outputs a digital signal to an output port 241 which can be similar to the output port 239.

It should be understood that the ports 239, 241, 243, 245 can use analog or digital connectors depending on the type of signal, as is understood by those skilled in the art.

The module 200 can be enclosed in a housing 203. The board 207 is secured to the housing 203. In this embodiment the ports 239, 241, 243, 245 are also secured to the housing 203. Also, the analog-to-digital converters 231, 233 or power meters are within the housing 203, even if not mounted to the board 207.

Calibration of the module 200 is simple compared to the prior art. The ports 239, 241, 243, 245 can be connected to a calibrated network analyzer and computer and outputs measured for known inputs. This calibration can be performed at the factory where the module 200 is factory calibrated as a unit. The calibration can also be performed at the site of the user.

In the foregoing specification, the invention has been described with reference to specific exemplary embodiments thereof. The specification and drawings are, accordingly, to be regarded in an illustrative sense rather than a restrictive sense.

1. A module for measuring power transmitted from and received by a system under test comprising:
a board;
a through path mounted to the board;
a first power sensor mounted to the board;
an input of the through path for receiving a first signal;
an output of the through path for outputting the first signal; and
a first coupler for coupling to the through path and for transmitting a portion of the first signal to the first power sensor for measuring power of the first signal.

2. The module of claim 1, wherein the output of the through path is also for receiving a second signal; and further comprising:
a second power sensor mounted to the board; and
a second coupler for transmitting a portion of the second signal to the second power sensor.

3. The module of claim 1, wherein the output of the through path is also for receiving a second signal; and further comprising:
a second coupler for transmitting a portion of the second RF signal to a measurement device external from the module.

4. The module of claim 1, further comprising coaxial cable plugs electrically connected to the input and output of the through line.

5. The module of claim 1, further comprising a housing enclosing the module.

6. The module of claim 1, wherein the power sensor is a diode-based power detector.

7. The module of claim 1, further comprising:
a housing enclosing the module; and
an output port of the housing for outputting a power measurement signal indicating the power measured by the first power sensor.

8. The module of claim 1, further comprising:
an analog-to-digital converter mounted to the board for converting a power measurement signal indicating the power measured by the first power sensor into a digital signal; and
a digital output port of the housing for outputting the digital signal.

9. The module of claim 8, wherein the digital output port is a USB port.

10. The module of claim 1, further comprising:
a housing enclosing the module;
an analog-to-digital converter within the housing for converting a power measurement signal indicating the power measured by the first power sensor into a digital signal.

11. The module of claim 1, further comprising:
a power meter mounted on the board for converting a power measurement signal indicating the power measured by the first power sensor into a digital signal; and
a digital output port of the housing for outputting the digital signal.

12. The module of claim 1, wherein the first power sensor is mounted on the board using SMT.

13. The module of claim 1, wherein the module is factory calibrated as a unit.

14. The module of claim 1, wherein the through path and the first coupler are etched onto the board.

15. The module of claim 1, wherein the first coupler is microstrip directional coupler.

16. The module of claim 1, wherein the board is a printed-circuit board.

17. The module of claim 1, wherein the board is an integrated-circuit substrate.

18. The module of claim 1, wherein the board is a ceramic substrate.
